(19) United States
(12) Patent Application Publication
(10) Pub. No.: US 2017/0030985 A1
(43) Pub. Date: Feb. 2, 2017

(54) Device for Subdividing Magnetic Field and Simultaneous Detection of Magnetic Resonance Signals from Multiple Sample Compartments

(71) Applicant: Rex E. Gerald, II, Willow Springs, IL (US)

(72) Inventor: Rex E. Gerald, II, Willow Springs, IL (US)

(73) Assignee: The Curators of the University of Missouri, Columbia, MO (US)

(21) Appl. No.: 15/223,979

(22) Filed: Jul. 29, 2016

Related U.S. Application Data
(60) Provisional application No. 62/199,112, filed on Jul. 30, 2015.

(51) Int. Cl. G01R 33/46; G01R 33/30; G01N 24/08

(52) U.S. Cl. CPC G01R 33/4625; G01N 24/08; G01R 33/30

(57) ABSTRACT

Devices and methods are provided for simultaneously interrogating multiple samples using NMR spectroscopy. A first magnetic field is induced. A flow of electricity is induced through a conductive material. The flow of electricity has a direction that is perpendicular to the first magnetic field, and the flow of electricity induces a second magnetic field. A first sample is placed in an additive magnetic field region, where a direction of the first magnetic field and a direction of the second magnetic field are aligned within the additive magnetic field region. A second sample is placed in a canceling magnetic field region, where the direction of the first magnetic field and the direction of the second magnetic field are opposed within the canceling magnetic field region. A free induction decay (FID) of at least the first and second samples is induced.

### CROSS-REFERENCE TO RELATED APPLICATION

This application claims the benefit of U.S. Provisional Patent Application No. 62,199,112, filed Jul. 30, 2015, entitled “Device for Subdividing Magnetic Field and Simultaneous Detection of Magnetic Resonance Signals from Multiple Sample Compartments.”

### GRANT STATEMENT

None.

### FIELD OF THE INVENTION

The present invention relates to the field of nuclear magnetic resonance (NMR) spectroscopy, more specifically, to a device/method for subdividing magnetic field and simultaneous detection of magnetic resonance signals from multiple sample compartments.

### BACKGROUND OF THE INVENTION

Chemical, compositional, and homogeneity analyses by benchtop NMR spectroscopy is an emerging field, which substantially reduces the time and cost of sample analyses for the chemical and food industries. Benchtop NMR spectroscopy and imaging are methods of analyses that are particularly suitable for on-line monitoring of processes that involve chemical reactions and mixing of substances such as foodstuffs. A limitation of benchtop NMR instrumentation is that only one sample can be analyzed at a time; samples must be inserted into the instrument and analyzed sequentially. In order to increase the sample throughput, multiple instruments must be purchased, installed, and operated simultaneously and in parallel.

### SUMMARY OF THE INVENTION

A high-level overview of various aspects of the invention is provided here for that reason, to provide an overview of the disclosure and to introduce a selection of concepts that are further described below in the detailed description section below. This summary is not intended to identify key features or essential features of the claimed subject matter, nor is it intended to be used as an aid in isolation to determine the scope of the claimed subject matter.

Embodiments described herein provide for a device for subdividing magnetic field and simultaneous detection of magnetic resonance signals from multiple sample compartments. The inventive device employs a combination of direct currents and/or radio frequency alternating currents to subdivide a transverse static magnetic field, typically provided by a commercial benchtop NMR spectrometer (or other conventional NMR spectrometer), into multiple volumes that can each test an individual sample. The inventive device deployed with a benchtop NMR (or other conventional NMR) comprises i) at least one electrically conducting member (the “conductor”), ii) at least one power current source for the conductor, and iii) a sample holder compartmentalized according to the subdivided transverse static magnetic field. The inventive device may further comprise a control/analysis means, such as a software module, for simultaneously collecting and processing NMR data from multiple samples.

According to one embodiment of the invention, the inventive device deployed with a benchtop NMR comprises at least one conductor connected and energized by a direct current power source to produce a magnetic field (B_{DC}). The conductor may be co-located within a permanent magnetic field (B_{O}) generated by the benchtop NMR. Further, the B_{DC} subdivides the B_{O} into one or more spaces where the nuclear spins contained in one or more individual samples may be interrogated, manipulated and/or analyzed for useful information.

According to another embodiment of the invention, the inventive device deployed with a benchtop NMR comprises at least one conductor connected and energized by radio-frequency alternating current amplifiers to produce a radio frequency magnetic field (B_{AC}). The conductor may be co-located within a permanent magnetic field (B_{O}) generated by the benchtop NMR. Further, the B_{AC} elicits B_{O} magnetic resonance signals from one or more independent samples.

According to yet another embodiment of the invention, the inventive device deployed with a benchtop NMR comprises at least one conductor, co-located with a permanent magnetic field (B_{O}) generated by the benchtop NMR, connected and energized by both direct current power source and radio-frequency alternating current amplifiers to simultaneously produce the following: (a) direct current magnetic field (B_{DC}) to subdivide the B_{O}; and (b) radiofrequency alternating current magnetic field (B_{AC}) to elicit magnetic resonance signals from one or more samples contained in compartments positioned at the nexus of the transverse static magnetic field, direct current magnetic fields, and the radio-frequency alternating current magnetic fields.

Furthermore, a method for using the inventive device with a commercial benchtop NMR spectrometer for multi-nuclear analyses, high sample throughput and on-line monitoring of chemical processes is also described herein.

### DESCRIPTION OF DRAWINGS

FIG. 1 is a schematic diagram of the inventive device deployed with a commercial benchtop NMR, in accordance with an embodiment herein;

FIG. 2 is a side-view diagram of the magnetic field when only DC current is conducted via the conductor L, in accordance with an embodiment herein;

FIG. 3 is a magnetic field isometric drawing when only DC current is conducted via the conductor L, in accordance with an embodiment herein;

FIG. 4 is a magnetic field isometric drawing when both DC current and radio-frequency alternating current are conducted via the conductor L, in accordance with an embodiment herein;

FIG. 5 illustrates the effects on the proton NMR spectrum of ethanol contained in two capillary tubes parallel and equidistant in opposite directions from the conductor L (with current i) caused by the subdivision of the static transverse magnetic field provided by the Magritek Spinsolve NMR spectrometer, a commercially available instrument, in accordance with an embodiment herein;

FIG. 6 depicts one configuration of components of a system, according to one embodiment of the disclosure; and

FIG. 7 depicts another configuration of components of a system, according to another embodiment of the disclosure.

### DETAILED DESCRIPTION

The subject matter of the present invention is described with specificity herein to meet statutory requirements. However, the description itself is not intended to limit the scope of this patent. Rather, the inventors have contemplated that the claimed subject matter might also be embodied in other ways, to include different steps or combinations of steps similar to the ones described in this document, in conjunction with other present or future technologies. Moreover, although the terms “step” and/or “block” may be used herein to connote different elements of methods employed, the terms should not be interpreted as implying any particular order among or between various steps herein disclosed unless and except when the order of individual steps is explicitly described.

Nuclear magnetic resonance spectroscopy is a research technique that allows researchers to determine the physical and chemical properties, such as the structure, dynamics, and reaction state, of molecules or the atoms contained within molecules. This information can, for instance, be used in various techniques to identify an unknown sample as a particular chemical compound, or to determine the concentration of a compound within a sample. When certain molecules, for example organic molecules, are placed in a strong magnetic field, atoms within the molecules will absorb and resonate only at specific radio frequencies. The radio frequencies absorbed are characteristic of the atoms in the compound, but are also highly dependent on the strength of the magnetic field those atoms are exposed to. This dependence on the strength of the magnetic field plays an important role in the amount of information that NMR spectroscopy can provide. In addition to the strong magnetic field applied externally across the entire sample, the magnetic field around a particular atom within a molecule is also impacted by what is called the electronic environment that atom is in. The electronic environment depends on the structure of the molecule, the form and nature of its chemical bonds, and other physical and chemical properties of the sample. Whereas the characteristic resonant frequencies by themselves can provide information about the presence and relative abundance of atoms within the sample, the electronic environment of each atoms causes a shift in the atom's resonant frequency, called a chemical shift, due to changes in the local magnetic field around the atom, thus providing additional information about that atom's electronic environment and, by extension, insight into the properties of the molecule.

By exposing a sample to a strong magnetic field and then applying a radio frequency pulse, generally referred to as interrogation pulse, a sample can be caused to undergo free induction decay (FID). This is somewhat analogous to striking a bell, wherein the interrogation pulse is the hammer and the FID is the tone generated by the bell. A spectrum can be generated from the FID. The x-axis of such a graph corresponds to the small variations in the resonant frequencies of the atoms in the sample that are attributable to the electronic environment of the atoms. The x-axis is thus referred to as the chemical shift axis. The y-axis corresponds to the strength of the signal at that frequency. Analysis of such spectra provide researchers with information that can be used, for example, to determine the identity of chemicals present in the sample, as well as with other physical and chemical properties of the sample.

Exposing a sample to a highly uniform and static magnetic field allows for smaller variations in the spectrum produced by the sample to be detected, which in turn allows for more detailed analysis. However, the spectra generated for various samples under a highly uniform and static magnetic field will all fall within a narrow band of resonant frequencies. As a result, it is not possible to separately analyze two samples simultaneously in a single sample space under such and static field, as the spectra for the two samples will be superimposed on one another will become indistinguishable. If instead, the magnitude of the magnetic field in one portion of the sample space is increased while the magnitude of the magnetic field in a second portion of the sample space is simultaneously decreased, resonant frequencies of the samples in each region will be shift away from samples in the opposite region along the chemical shift axis, and the spectra for samples placed in the separate regions can become distinct, with no portion of the spectra overlapping.

Embodiments herein provide for a device and method for subdividing magnetic field and simultaneous detection of magnetic resonance signals from multiple sample compartments. The inventive device employs at least one electronically conducting element (“conductor”) to generate static and/or oscillating magnetic fields within a transverse static magnetic field provided by an conventional NMR spectrometer (such as a commercial benchtop NMR manufactured by Magritek) for multi-nuclear analyses, high sample throughput, and on-line monitoring of chemical processes.

More specifically, the inventive device, deployed with a conventional NMR spectrometer, may comprise at least one conductor, current sources (or current power unit) for the conductor, and a compartmentalized sample holder. The conductor may be co-located in or near a single-purpose transverse static magnetic field generated by the conventional NMR spectrometer. The conductor may be energized by a high-stability direct current (DC) current power source, a radio-frequency alternating current (AC) current source (with radio-frequency tune capacitors and radio-frequency match capacitors), or a combination of both DC and AC sources, to generate static and/or oscillating magnetic fields that subdivide the transverse static magnetic field. The sample holder is positioned within the subdivided magnetic field with each compartment having a predetermined magnitude of either one or both static and alternating magnetic fields (net magnetic fields).

The material used to fabricate the conductor can be from the category of materials known as metals and semi-metals, including copper, gold, silver, aluminum, etc. and combinations of metals in the form of alloys, including bronze, phosphor-bronze, etc. The shapes of conductor could be, for exemplary purposes only, round, square, triangle, or the like, and could be cross-section and straight, curved, twisted, or the like and of various lengths.

The DC current conducted by the conductor may range from 0.00001 to 100 amps, such as from 0.1 to 10 amps, or from 1 to 5 amps when deployed with a commercial benchtop NMR. The AC current conducted by the conductor may range from 0.00001 to 1000 amps, such as from 0.1 to 100 amps, or from 1 to 10 amps when deployed with a commercial benchtop NMR.

In a first aspect, a method is provided for simultaneously interrogating multiple samples using NMR spectroscopy. The method includes inducing a first magnetic field, inducing a flow of electricity through a conductive material, wherein the flow of electricity induces a second magnetic field. In some embodiments, the flow of electricity comprises one or more of a direct current or at least one excitation pulse of radio frequency (RF) alternating current. In some embodiments, the at least one excitation pulse selectively acts on at least one of the first sample and the second sample. In some embodiments, the flow of electricity has a direction that is perpendicular to the first magnetic field, while in other embodiments the flow may be parallel to the magnetic field or at some other angle to the field. The method further comprises placing a first sample in an additive magnetic field region, wherein a direction of the first magnetic field and a direction of the second magnetic field are aligned within the additive magnetic field region. Further, the method includes placing a second sample in a canceling magnetic field region, wherein the direction of the first magnetic field and the direction of the second magnetic field are opposed within the canceling magnetic field region.

In some embodiments, the method comprises placing a third sample in an intermediary magnetic field region. The intermediary magnetic field region comprises an intermediary magnetic field having a magnitude less than a magnitude of the additive magnetic field and greater than a magnitude of the canceling magnetic field. Also, the method includes inducing an FID of at least the first and second samples. In some embodiments, the method further comprises generating a graph of a NMR spectrum for at least the first and second samples. In some embodiments, the graph of the NMR spectrum has a signal intensity and a chemical shift axis. The NMR spectrum comprises at least a first spectrum and a second spectrum, the first spectrum being spaced out and distinct from the second spectrum along the chemical shift axis.

In a second aspect, a method is provided for simultaneously interrogating multiple samples using NMR spectroscopy. The method includes exposing a first sample to a first magnetic field in a sample space of an NMR spectrometer, wherein the sample space includes a conductor extending therethrough. In some embodiments, the first magnetic field comprises a combination of a transverse magnetic field and a circular magnetic field centered at the conductor, wherein the traverse magnetic field and the circular magnetic field may be configured in various ways including parallel to produce an additive magnetic field, antiparallel to produce a canceling magnetic field, or perpendicular proximate to the first sample. The method further comprises exposing a second sample to a second magnetic field in the sample space of the NMR spectrometer, wherein the first and second samples are positioned on opposing sides of the conductor. In some embodiments, the distance between the first sample and the conductor is less than the distance between the second sample and the conductor. The method also provides monitoring a free induction decay (FID) of at least the first and the second samples, and generating a NMR spectrum for at least the first and the second samples, wherein the NMR spectrum comprises a first spectrum corresponding to the first sample and a second spectrum corresponding to the second sample. In some embodiments, the method comprises inducing a sequence of radio frequency (RF) pulses in the conductor, such that the sequence selectively acts on the first sample, such as to prevent detection of the first sample in the NMR spectrum or such that the first sample cancels some portion of the spectrum of the second sample.

In a third aspect, a device is provided for simultaneous monitoring of multiple samples using a single sample NMR spectrometer. The device comprises an electrical conductor, and a compartmentalized sample holder having a center and a perimeter configured to accept a plurality of NMR sample tubes around the perimeter and further configured to allow the electrical conductor to pass through the center. In some embodiments, the sample holder is configured to accept at least a first and second sample tube. The first and second are located on opposite sides of the conductor. Further, the device comprises a power source coupled to the electrical conductor, wherein the power source comprises a direct current (DC) power supply. In some embodiments, the power source further comprises an alternating current (AC) power supply, such as a radio frequency (RF) power amplifier. In some embodiments, the device further comprises a first and second variable tuning capacitor. The first variable tuning capacitor is connected proximate to a first terminal of the conductor and the second variable tuning capacitor is connected proximate a second terminal of the conductor.

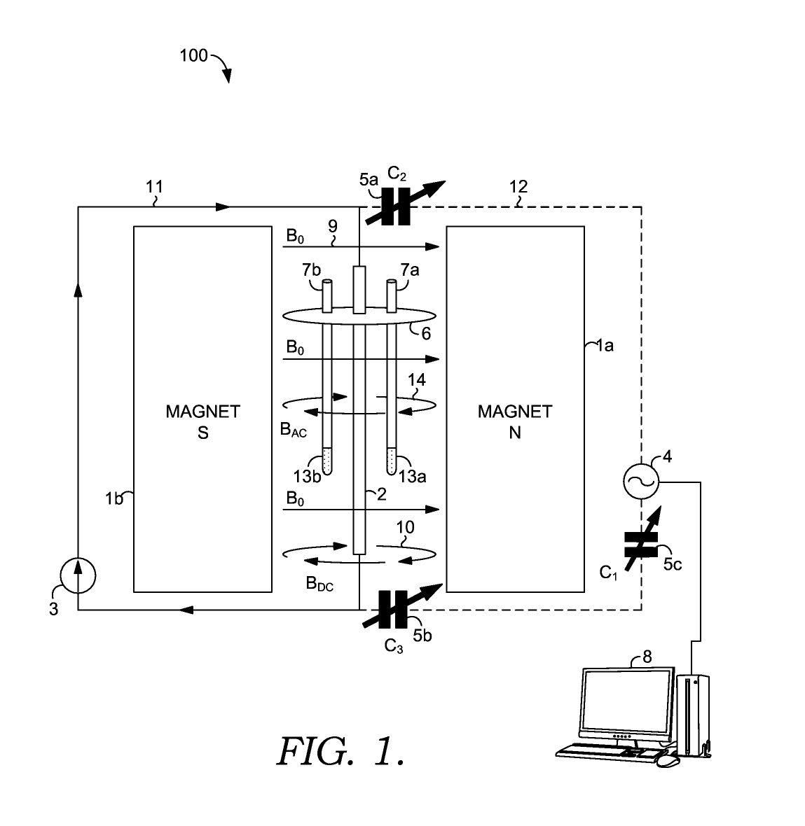

Turning now to FIG. 1, a schematic diagram is illustrated of a device 100 deployed with a commercial benchtop NMR. As shown in FIG. 1, the inventive device comprises conductor 2 which is co-located (such as positioned in the center region of) with the magnetic field (B_{O}) 9 generated by magnets 1a and 1b of the benchtop NMR. Device 100 further comprises sample holder 6 compartmentalized with multiple chambers having pre-determined net magnetic fields. Further, device 100 comprises DC circuit 11 comprising current power unit 3 (DC power supply) and AC circuit 12 comprising alternating current power unit 4 (AC power amplifier). In some implementations, alternating current may be desired. In such cases, additional radio-frequency tune capacitors/radio-frequency match capacitors 5a through 5c may be included in AC circuit 12 to provide broadband radio-frequency pulses for detecting radio-frequency ignals. In some embodiments, both DC power supply 3 and AC power amplifier 4 can be employed. The radio-frequency alternating current may be supplied by NMR console 8. NMR console 8 may be part of the benchtop NMR spectrometer or an independent NMR console.

FIG. 1 also illustrates the orientation of transverse magnetic field B_{O} 9 produced by magnets 1a and 1b and circular magnetic field B_{DC} 10 produced by the direct current i in conductor 2. In some embodiments, magnets 1a and 1b may be permanent magnets, while in other embodiments magnets 1a and 1b may be electromagnets. Due to the superposition of transverse magnetic field B_{O} 9 and circular magnetic field B_{DC} 10, this arrangement produces a region where the magnetic fields are aligned and thus the magnitude of the net magnetic field in this region is then additive. This arrangement also produces a region where the magnetic fields are opposed, thus the magnitude of the net magnetic field is then canceling in this region.

Furthermore, in FIG. 1, a vertical container with sample tubes 7a and 7b for NMR analyses are illustrated being positioned in the net static magnetic field (B_{O} 9 subdivided by B_{DC} 10) at designated positions in sample holder 6. Samples 13a and 13b are located inside of sample tubes 7a and 7b, respectively, and are interrogated by a radio frequency magnetic field (not shown) produced by conventional means. Samples 13a and 13b can also be interrogated by a radio frequency magnetic field B_{AC} 14 produced by alternating current (AC) power amplifier 4 in conductor 2. The radio frequency alternating current is generated by the NMR console 8 and coupled through capacitor C1 5c to a resonant circuit composed of the conductor 2 and capacitors C2 5a and C3 5b. While B_{AC} and B_{DC} are illustrated separately in FIG. 1, in reality they may exist in the same space and would not be spatially distinguishable.

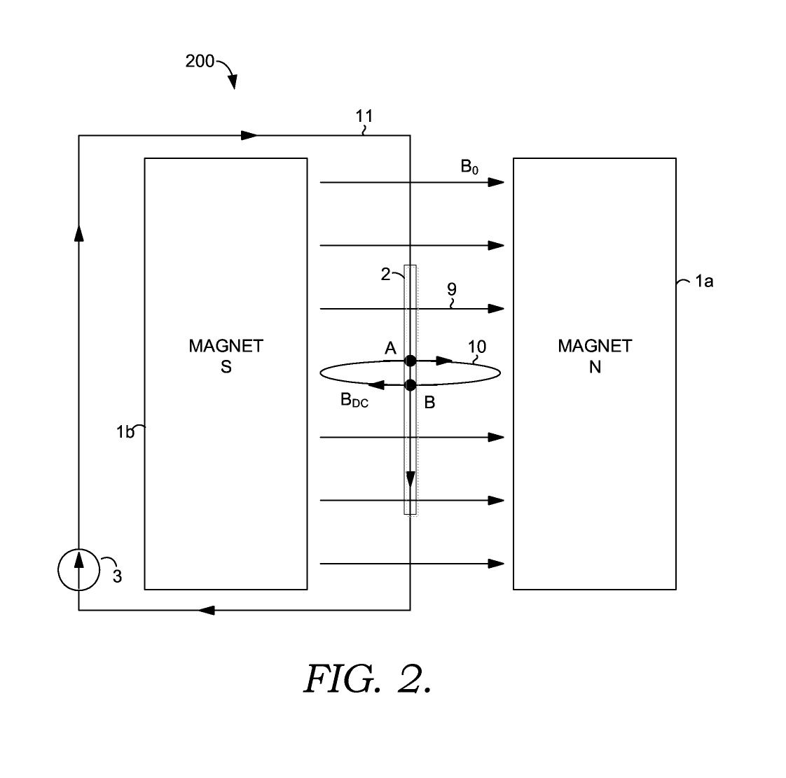

Referring to FIG. 2, a side-view diagram 200 of the subdivided magnetic field of FIG. 1 is shown, when only DC current is generated through the conductor L2. FIG. 2 illustrates the orientation of the magnetic field B_{O} 9 produced by a transverse magnet and a circular magnetic field B_{DC} produced by direct current i in the conductor L generated by the DC power supply. The shape of B_{DC} 10 may vary depending on the geometrical shape of conductor 2 employed and the position and orientation in which conductor 2 is located.

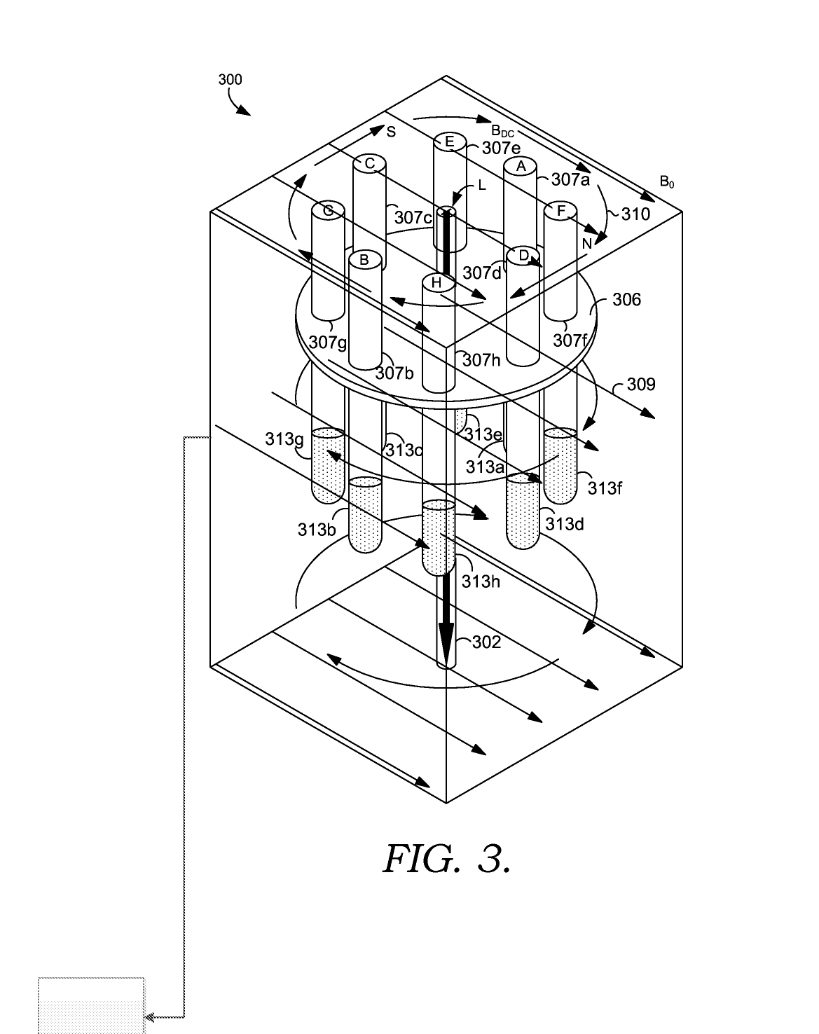

FIG. 3 illustrates a magnetic field diagram 300 where DC current flow is induced through the conductor L 302. FIG. 3 illustrates the positions A, B, C, D, E, F, G and H (items 307a though 307h, respectively) for eight sample tubes holding samples 313a through 313h, respectively, in relation to the magnetic field B_{O} 309 produced by the permanent magnet and the circular magnetic field B_{DC} 310 produced by the direct current i in the conductor L 302. As depicted in FIG. 3, magnetic field B_{O}309 and circular magnetic field B_{DC} 310 are parallel at and just surrounding position A 307a and are antiparallel or are opposing at and just surrounding position B 307b. As a result, the magnitude of the total magnetic field (the “net magnetic field”) experienced by samples in positions A 307a and B 307b are B_{O}+B_{DC} and B_{O}−B_{DC}, respectively. Due to the magnetic field B_{O} 309 and circular magnetic field B_{DC} 309 being perpendicular to one another, the magnitude of the net magnetic field experienced by both samples in positions C and D is \sqrt{B_{O}²+B_{DC}²}. The net magnetic field experienced by samples in positions E, F, G and H 307e though 307h, as well as other samples at other potential positions, can be calculated using the Law of Sines. Samples in positions A through H (items 307a through 307h, respectively) are also interrogated by a radio frequency magnetic field (not shown) produced by a conventional NMR console. Rotation of the sample holder by increments of 45 degrees provides a means to interrogate samples in positions A-H (items 307a through 307h, respectively) by various methods. Multiple sample positions, besides the exemplary positions A through H (items 307a through 307h, respectively), each with a net magnetic field, can be determined and designated on the sample holder 306.

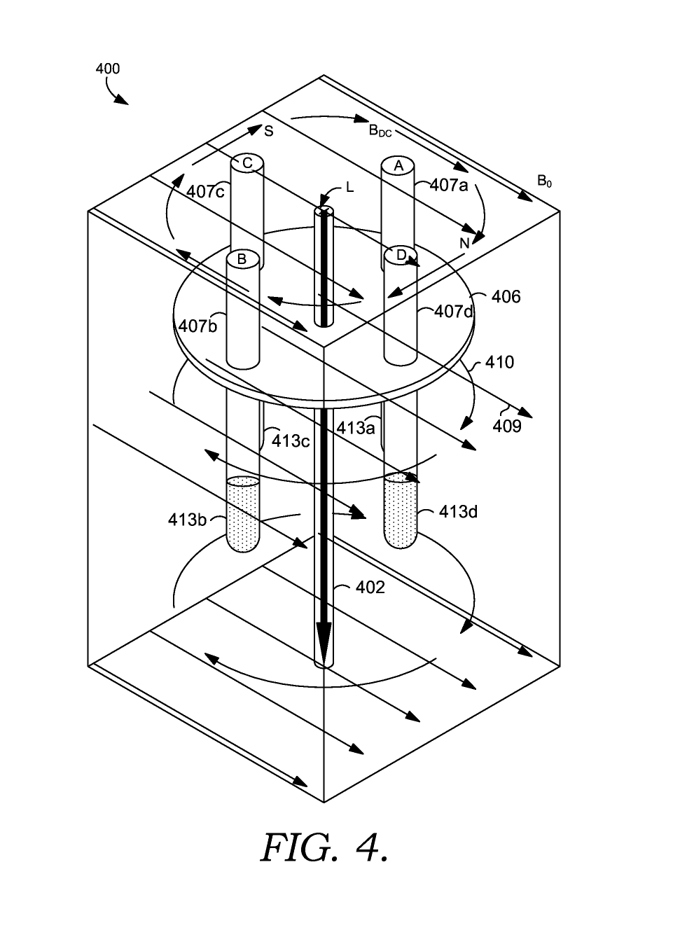

Referring now to FIG. 4, FIG. 4 illustrates an exemplary diagram 400 of a magnetic field when DC current and radio-frequency (RF) alternating current (AC) are generated through the conductor L 402. FIG. 4 illustrates the exemplary positions of four samples 407a through 407d in relation to magnetic field B_{O} 409 produced by the permanent magnet and circular magnetic field B_{DC} 410 produced by the direct current i in the conductor L 402. The magnitude of the total magnetic fields (the “net magnetic field”) experienced by samples in positions A, B, C, and D (items 407a through 407d, respectively) are B_{O}+B_{DC}, BC_{O}−B_{DC}, \sqrt{B_{O}²+B_{DC}²}, and \sqrt{B_{O}²+B_{DC}²}, respectively.

Samples in positions A through D (items 407a through 407d, respectively) are interrogated by a radio frequency magnetic field (not shown). In some embodiments, the radio frequency magnetic field may be produced by the benchtop NMR console. The NMR spectra for samples in positions A and B 407a and 407b are separately resolved by the action of magnetic field B_{DC} 410, but the spectra for samples in positions C and D 407c and 407d are overlapped. Samples in positions C and D 407c and 407d are independently interrogated by a radio frequency magnetic field B_{AC}, which corresponds to circular magnetic field 410 produced by alternating current in conductor L 402 produced by the power amplifier. Because both B_{DC} and B_{AC} are produced by current flowing through conductor L 402, these fields coexist spatially. Due to this strong correlation between B_{AC} and circular magnetic field 410, radio frequency magnetic field B_{AC} is not shown independent of circular magnetic field 410 in FIG. 4. Therefore, samples in positions A and B 407a and 407b and samples in positions C and D 407c and 407d are alternately interrogated for useful purposes. Samples in positions A and B 407a and 407b are effectively interrogated by radio frequency magnetic field, B_{AC}. In some embodiments, radio frequency magnetic field, B_{AC} may be produced by the benchtop NMR.

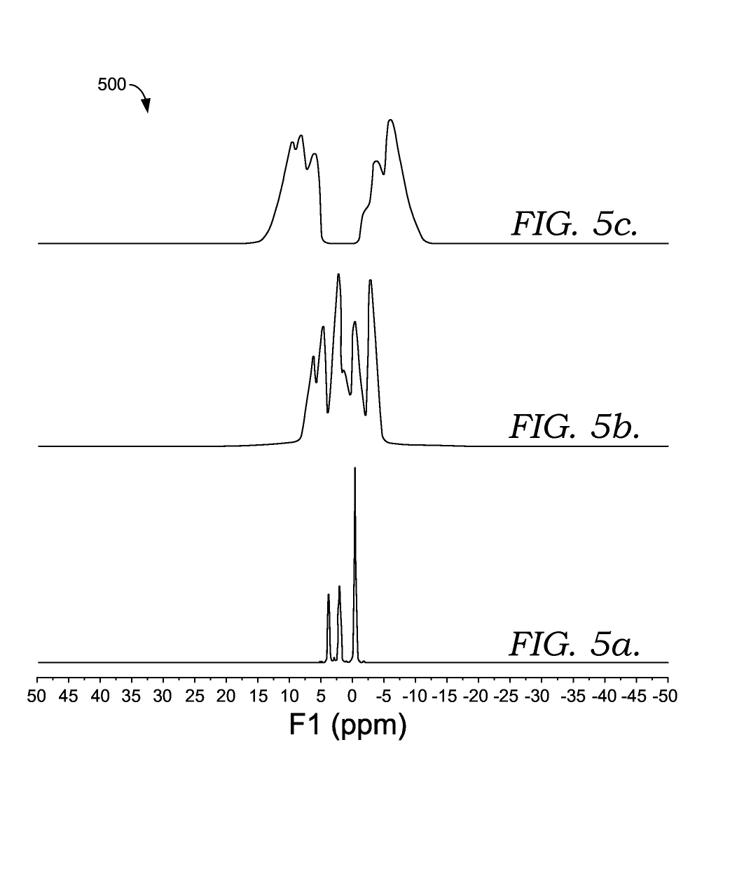

FIG. 5 illustrates a plurality of graphs (collectively referred to as item 500) that depict the spectra of a plurality of tests of two samples under different magnitudes of circular magnetic field B_{DC}. FIG. 5(a) depicts the spectra for two samples under a homogeneous transverse magnetic field B_{O}. The magnitude of circular magnetic field B_{DC}=0 T. This may be the case when conductor 2 is absent from the apparatus, or where current i=0 mA through conductor 2. As depicted, the spectra from both samples are exactly overlapping. FIG. 5(b) depicts the same two samples as depicted in FIG. 5(a) under a subdivided field where the current through conductor 2, i=20.0 mA. As depicted, the spectra from both samples are partially overlapping. FIG. 5(c) depicts the same two samples as before now under the subdivided magnetic field where the current through conductor 2, i=50.9 mA. As depicted, the spectra from both samples separate apart, which can provide independent NMR analysis for both samples. In some embodiments, the application of X and X3 magnetic field gradient shims can further improve the spectral resolution (not shown).

Some embodiments of the device described herein may be assembled by co-locating the conductor approximately along the vertical center of a NMR spectrometer magnet, such as a Magritek Spinsolve benchtop spectrometer. In some embodiments, the conductor may be a 20-gauge bare copper wire 30 cm in length. The top end of the conductor may be connected to the positive terminal and the bottom end to the negative terminal of an adjustable direct current (DC) power supply. In some embodiments, the DC power supply may supply a power range between 0-10 volts and 0-5 amps. In some embodiments, the DC power supply may be set to current limiting mode and adjusted to supply approximately 0.1 volt and 2.0 amps of highly-regulated and stable current.

A sample holder device may be fabricated as a flat, thin disk and may comprise a central hole to allow passage of the conductor, and a plurality of sample tube holes located on the disk perimeter and capable of holding a plurality of NMR tubes. The sample holder may be fabricated from plastic or other similar material that is compatible with NMR analyses of the samples. In one embodiment, the sample holder device may comprise two sample tube holes around the conductor spaced 180 degrees apart, separated along the diameter of the disk. In some embodiments the sample tube holes may be separated by 4.0 mm. In other embodiments, the sample tube holder device may be adjustable to allow for sample tube of various sizes and shapes to be used. The distance between the sample tube and the conductor may be adjustable. In yet other embodiments, the sample tubes may comprise 1 mm glass capillary tubes and may be 20-cm long. In some embodiments, the sample tube may be designed to have a circular arc or crescent profile in order to conform to the circular character of the magnetic field generated by the conductor.

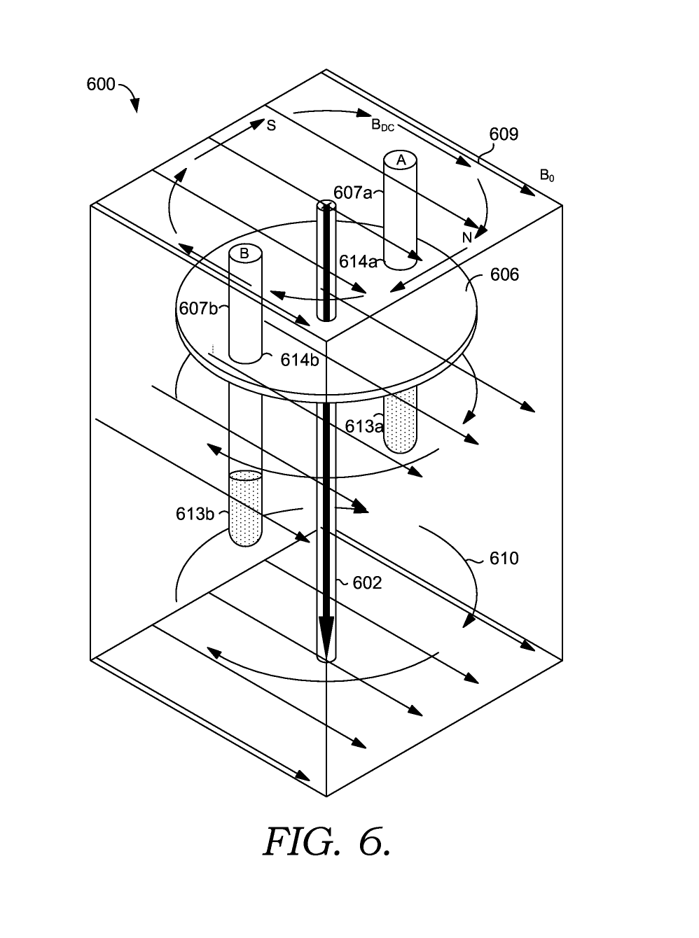

FIG. 6 depicts one configuration of components of a device 600, according to one embodiment herein. FIG. 6 shows a pair of capillary tubes 607a and 607b suspended in sample tube holes 614a and 614b of sample holder 606. As depicted, the positions of capillary sample tubes 607a and 607b are located with one at 90 degrees clockwise from the north pole and the other at 90 degrees counterclockwise from the north of the magnet that generates transverse magnetic field B₀ 609. Sample tubes 607a and 607b may be filled with solution samples 613a and 613b, respectively. In some embodiments, arranging samples 613a and 613b in this manner may be thereby located the samples in the proton NMR probe of the spectrometer. NMR software may then be used in a conventional manner to simultaneously interrogate a plurality sample solutions. The free induction decay (FID) data may be collected and converted into a spectrum. In some embodiments, the spectrum may consist of a plurality of complete proton NMR spectra that are disposed side-by-side along the chemical shift axis. The complete proton NMR spectrum for sample tube 614a may appear to the left side of the spectrum and the proton NMR spectrum for sample tube 614b may appear to the right side. The plurality of spectra may be contiguous but completely separate, with no overlapping portions.

In some instances, the spectral peaks may be somewhat broadened by the gradient in the magnetic field created by the current in the conductor. In some embodiments, NMR spectrometer shims commonly known as X and X³ can be used to sharpen the spectral peaks, if desired.

In another embodiment, the sample holder device may comprise four sample tube holes around the conductor spaced 90 degrees apart, as depicted in FIG. 4. In such embodiments, samples may be interrogated pairwise, with samples located on opposite sides of the sample holder (e.g. samples A and B 413a and 413b) interrogated simultaneously as disclosed above. In such a case, the spectra for samples C and D 413c and 413d will appear overlapped, between the spectra for samples A and B 413a and 413b, and can be ignored. The sample holder 406 may then be rotated clockwise by 90 degrees and the NMR interrogation procedure repeated for samples C and D 413c and 413d, in which case the spectra for samples A and B 413a and 413b will appear overlapped, between the spectra for samples C and D 413c and 413d, and can be ignored. Alternatively, in some embodiments, rather than rotating sample holder 406, interrogation of samples C and D 413c and 413d may be facilitated by modulating circular magnetic field B_{DC} 410, such as by reversing the direction of the current through conductor 402.

In implementations of the present invention, an AC power source is incorporated, as depicted in FIG. 1. In some embodiments, in addition to being connected to DC power source 3 disclosed above, the top end of conductor 2 may also be connected to one terminal of variable matching capacitor 5a with the bottom end to one terminal of matching capacitor 5b. The second terminal of first variable matching capacitor 5a is connected to AC power source 4. In some embodiments, AC power source 4 may be a radiofrequency (RF) power amplifier. The second terminal of second variable matching capacitor 5b may be connected to one terminal of variable tuning capacitor 5c. The second terminal of variable tuning capacitor 5c may be connected to AC power source 4 to complete a resonant circuit.

In such embodiments, AC power source 4 may be used to eliminate the overlapping spectra, for example, of samples C and D 413c and 413d of FIG. 4 while samples A and B 413a and 413b are being interrogated. This is possible due to the fact that B₀ 409 at samples C and D 413c and 413d is perpendicular to magnetic field 410 generated by conductor L 402, while being parallel to the field at samples A and B 413a and 413b. As such, the magnetic field can induce a rotation in the spin magnetization of samples C and D 413c and 413d but not at samples A and B 413a and 413b.

In such cases, immediately prior to the interrogation pulse by the spectrometer, an excitation pulse may be provided via conductor 402. In some embodiments, the excitation pulse may be provided by an NMR console. In this way, the excitation pulse may selectively rotate the sample spin magnetizations of samples C and D 413c and 413d by 90 degrees, and does not affect the sample spin magnetizations of sample A and B. When the samples are then interrogated, all of the samples will be rotated 90 degrees, resulting in a 180 degree rotation in samples C and D 413c and 413d. This 180 degree rotation results in the spectra for samples C and D 413c and 413d to not appear in the resulting NMR graph.

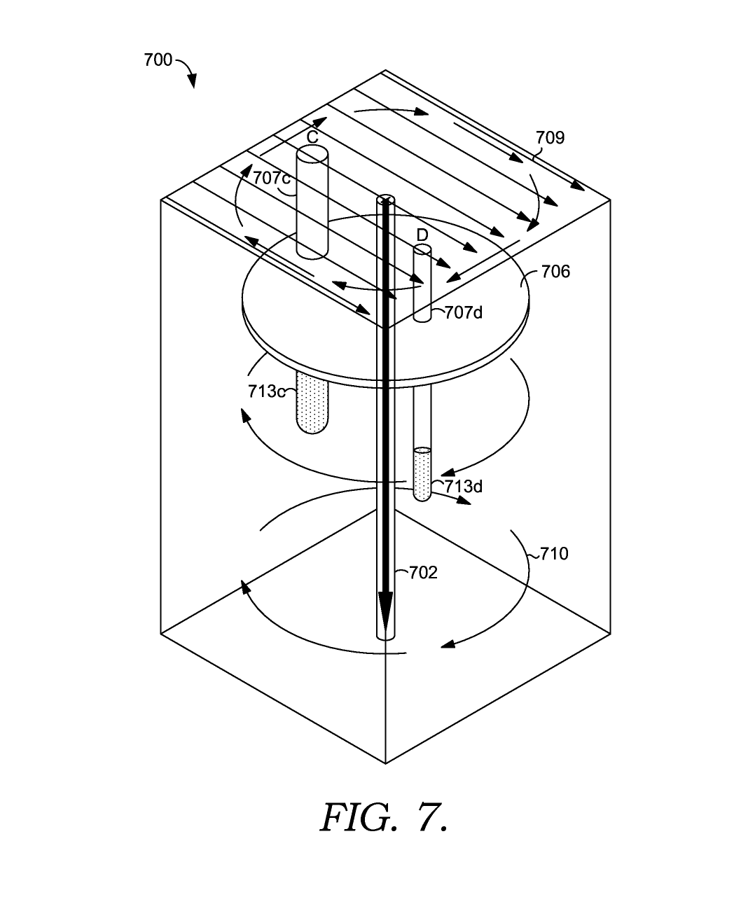

FIG. 7 depicts another configuration of components of a system 700 according to another embodiment provided herein. FIG. 7 shows an embodiment wherein sample tube 707d is located towards the south and sample tube 707c is located towards the north pole of the magnet that generates transverse magnetic field B₀ 709. In some embodiments, transverse magnetic field B₀ 709 may be generated by a permanent magnet built into a desktop NMR spectrometer. As depicted, sample D 713d is half the size of sample C 713c and the distance from sample D 713d to the conductor 702 is half the distance from sample C 713c to the conductor. Sample D 713d may contain a solute in a solvent, while sample C 713c may contain the solvent alone. When samples 713c and 713d are interrogated in this configuration, the resulting spectrum consists of two complete proton NMR spectra that may be superposed on each other, sharing a substantially identical chemical shift axis. In such a case, the complete proton NMR spectrum sample D 713d may reveal the solute and solvent peaks, and the proton NMR spectrum for sample C 713c may reveal only the solvent peak. The two spectra would thus be superposed but derived from completely separate NMR signals, with completely overlapping solvent peaks. The two solvent peaks from sample C and D 713c and 713d can be made to cancel each other so that the entire dynamic range of the NMR spectrometer receiver and analogue-to-digital converter can be utilized to detect and more accurately meter the intensities of the solute peaks. To accomplish the mutual annihilation of the NMR signals that produce the two solvent peaks, a radiofrequency electromagnetic pulse of finite duration and amplitude can be provided to central conductor 702 from an AC power amplifier. Since the strength of magnetic field 710 generated conductor 702 is a function of distance from conductor 702, the proton magnetization of sample D 713d will be roughly twice that of the effect on sample C 713c. The duration and amplitude of the RF pulse can be adjusted to correspond with the proton magnetization in sample D 713d, closer to conductor 702, executes a 360-degree rotation during the period of the RF pulse; while the proton magnetization in sample C 713c, being further from conductor 702, will simultaneously execute a 180-degree rotation during the period of the RF pulse. Thus, the proton magnetization in both capillary NMR tubes will be directed opposite to each other, and a 90-degree RF pules generated by the spectrometer is then used in a conventional manner to simultaneously immediately interrogate the sample solution and the solvent. The cancellation of the two solvent peaks results in a spectrum that only consists of solute peaks and a residual solvent peak. While the invention has been described in connection with specific embodiments thereof, it will be understood that the inventive device is capable of further modifications. This disclosure is intended to cover any variations, uses, or adaptations of the invention following, in general, the principles of the invention and including such departures from the present disclosure as come within known or customary practice within the art to which the invention pertains and as may be applied to the essential features herein before set forth.

Aspects of the current disclosure are directed to a device for simultaneous monitoring of multiple samples using NMR spectroscopy. The device comprises a first magnet. The device further comprises an electrical conductor. The device further comprises a power source coupled to the electrical conductor. In some embodiments, the power source comprises a source of direct correct (DC) electricity. In some embodiments, the power source comprises a source of alternating current (AC) electricity. The device further comprises an additive field region. The device further comprises a cancelling field region. The device further comprises a first NMR sample tube positioned in the additive field region. The device further comprises a second NMR sample tube positioned in the cancelling field region.

### EXAMPLES

### Example 1

A procedure for assembling one embodiment of the inventive device includes co-locating a 20-gauge bare copper wire 30 cm in length (the conductor) approximately along the vertical center of a Magritek Spinsolve benchtop NMR spectrometer magnet. The top end of the conductor is connected to the positive terminal and the bottom end to the negative terminal of an adjustable direct current (DC) power supply that can supply 0-10 volts and 0-5 amps. The DC power supply should be set to current limiting mode and adjusted to supply approximately 0.1 volt and 2.0 amps of highly-regulated and stable current.

A sample holder device is fabricated as a flat thin plastic disk that has a central hole to allow passage of the 20-gauge bare copper wire conductor, and two holes 180 degrees apart, separated along the diameter of the disk by 4.0 mm, located on the disk perimeter and capable of holding two 1 mm glass capillary NMR tubes. Two 20-cm long, 1.0-mm diameter capillary tubes filled with solution samples and capped with 1.15-mm diameter plastic caps are suspended in the two perimeter holes of the plastic disk sample holder. The positions of the two glass capillary sample tubes are located one at 90 degrees clockwise from the north pole and the other 90 degrees counterclockwise from the north of the permanent NMR magnet. The samples are thereby also located in the proton NMR probe of the Magritek Spinsolve spectrometer.

The Magritek NMR software is used in a conventional manner to simultaneously interrogate both sample solutions. The free induction decay (FID) data is collected and converted into a spectrum. The spectrum consists of two complete proton NMR spectra that are disposed side-by-side along the chemical shift axis. The complete proton NMR spectrum for one capillary sample tube appears on the left side and the proton NMR spectrum for the second capillary tube appears on the right side. The two spectra are contiguous but completely separate, with no overlapping portions. The spectral peaks may be somewhat broadened by the gradient in the magnetic field created by the current in the conductor. The Magritek NMR spectrometer shims commonly known as X and X3 can be used to sharpen the spectral peaks, if desired. All data collection and processing is performed by the software package provided by Magritek.

### Example 2

A procedure for assembling another embodiment of the inventive device includes positioning a 20-gauge bare copper wire 30 cm in length (the conductor) approximately along the vertical center-axis of a Magritek Spinsolve benchtop NMR spectrometer magnet. The top end of the conductor is connected to the positive terminal and the bottom end to the negative terminal of an adjustable direct current (DC) power supply that can supply 0-10 volts and 0-5 amps. The DC power supply should be set to current limiting mode and adjusted to supply approximately 0.1 volt and 2.0 amps of highly-regulated and stable current.

A sample holder device is fabricated as a flat thin plastic disk that has a central hole to allow free passage of the 20-gauge bare copper wire conductor, and four holes 90 degrees apart, separated along the diameter of the disk by 4.0 mm, located on the disk perimeter and capable of holding four 1.0 mm glass capillary NMR tubes. Four 20-cm long, 1.0-mm diameter capillary tubes filled with solution samples and capped with 1.15-mm diameter plastic caps are suspended in the four perimeter holes of the plastic disk sample holder. The positions of two of the four glass capillary sample tubes are located one at 90 degrees counterclockwise from the north pole (sample 1) and the other 90 degrees clockwise from the north pole (sample 2) of the permanent NMR magnet. The positions of the other two glass capillary sample tubes are initially located one at the south pole (sample 3) and the other at the north pole (sample 4) of the permanent NMR magnet. The four samples are thereby also located in the proton NMR probe of the Magritek Spinsolve spectrometer.

The Magritek NMR software is used in a conventional manner to simultaneously interrogate all four sample solutions. The free induction decay (FID) data is collected and converted into a spectrum. The spectrum consists of four complete proton NMR spectra that are disposed side-by-side along the chemical shift axis. The complete proton NMR spectrum for one capillary sample tube (sample 1) appears on the left side and the proton NMR spectrum for the second capillary tube (sample 2) appears on the right side. The two spectra are contiguous but completely separate, with no overlapping portions. (The spectra for samples 3 and 4 will appear overlapped, between the spectra for samples 1 and 2, and can be ignored.) The spectral peaks may be somewhat broadened by the gradient in the magnetic field created by the current in the conductor. The Magritek NMR spectrometer shims commonly known as X and X3 can be used to sharpen the spectral peaks, if desired. The sample holder is then rotated clockwise by 90 degrees and the NMR interrogation procedure is repeated for samples 3 and 4. (The spectra for samples 1 and 2 will appear overlapped, between the spectra for samples 3 and 4, and can be ignored.) All data collection and processing is performed by the software package provided by Magritek.

### Example 3

A procedure for assembling yet another embodiment of the inventive device includes co-locating a 20-gauge bare copper wire 30 cm in length (the conductor) approximately along the vertical center of a Magritek Spinsolve benchtop NMR spectrometer magnet. The top end of the conductor is connected to the positive terminal and the bottom end to the negative terminal of an adjustable direct current (DC) power supply that can supply 0-10 volts and 0-5 amps. The DC power supply should be set to current limiting mode and adjusted to supply approximately 0.1 volt and 2.0 amps of highly-regulated and stable current. The top end of the conductor is also connected to one terminal of a variable matching capacitor and the bottom end to one terminal of a second matching capacitor. The second terminal of the first variable matching capacitor is connected to a radiofrequency (RF) power amplifier. The second terminal of the second variable matching capacitor is connected to one terminal of a variable tuning capacitor. The second terminal of the variable tuning capacitor is connected to the RF power amplifier to complete a resonant circuit.

A sample holder device is fabricated as a flat thin plastic disk that has a central hole to allow passage of the 20-gauge bare copper wire conductor, and four holes 90 degrees apart, located on the disk perimeter at 2.0 mm from the central hole, and capable of holding four 1 mm glass capillary NMR tubes. Four 20-cm long, 1.0-mm diameter capillary tubes, each filled with a solute and a solvent are capped with 1.15-mm diameter plastic caps and suspended in the two holes of the plastic disk sample holder. The positions of two of the four glass capillary sample tubes are located one at 90 degrees counterclockwise from the north pole (sample 1) and the other 90 degrees clockwise from the north pole (sample 2) of the permanent NMR magnet. The positions of the other two glass capillary sample tubes are initially located one at the south pole (sample 3) and the other at the north pole (sample 4) of the permanent NMR magnet. The four samples are thereby also located in the proton NMR probe of the Magritek Spinsolve spectrometer.

The Magritek NMR software and probe hardware is used in a conventional manner to simultaneously excite all four sample solutions via an excitation pulse that rotates the sample spin magnetizations by 90 degrees. However, immediately prior to the interrogation pulse by the Magritek Spinsolve spectrometer, an excitation pulse is provided by an NMR console via the 20-gauge copper wire conductor; the excitation pulse selectively rotates the sample spin magnetizations of samples 3 and 4 by 90 degrees, and does not affect the sample spin magnetizations of sample 1 and 2. The free induction decay (FID) data is collected and converted into a spectrum. The spectrum consists of two complete proton NMR spectra that are disposed side-by-side along the chemical shift axis. The complete proton NMR spectrum for one capillary sample tube (sample 1) appears on the left side and the proton NMR spectrum for the second capillary tube (sample 2) appears on the right side. The two spectra are contiguous but completely separate, with no overlapping portions. (The spectra for samples 3 and 4 will not appear.) The spectral peaks may be somewhat broadened by the gradient in the magnetic field created by the current in the conductor. The Magritek NMR spectrometer shims commonly known as X and X3 can be used to sharpen the spectral peaks, if desired. The sample holder is then rotated clockwise by 90 degrees and the NMR interrogation procedure is repeated for samples 3 and 4. (The spectra for samples 1 and 2 will not appear.) All data collection and processing is performed by the software package provided by Magritek.

### Example 4

A procedure for assembling yet another embodiment of the inventive device includes co-locating a 20-gauge bare copper wire 30 em in length (the conductor) approximately along the vertical center of a Magritek Spinsolve benchtop NMR spectrometer magnet. The top end of the conductor is connected to one terminal of a variable matching capacitor and the bottom end to one terminal of a second matching capacitor. The second terminal of the first variable matching capacitor is connected to a radiofrequency (RF) power amplifier. The second terminal of the second variable matching capacitor is connected to one terminal of a variable tuning capacitor. The second terminal of the variable tuning capacitor is connected to the RF power amplifier to complete a resonant circuit.

A sample holder device is fabricated as a flat thin plastic disk that has a central hole to allow passage of the 20-gauge bare copper wire conductor, and two holes 180 degrees apart, separated along the diameter, the first hole at 2.0 mm, located on the disk perimeter and capable of holding one 1 mm glass capillary NMR tube; the second hole at 1.0 mm, located on the disk halfway between the center hole and the perimeter and holding a second 1 mm glass capillary NMR tube. Two 20-cm long, 1.0-mm diameter capillary tubes, one filled with a solute and a solvent and the second filled only with the identical solvent are capped with 1.15-mm diameter plastic caps and suspended in the two holes of the plastic disk sample holder. The positions of the two glass capillary sample tubes arc located one at the south and the other at the north pole of the permanent NMR magnet, or at other positions. The samples are thereby also located in the proton NMR probe of the Magritek Spinsolve spectrometer.

The Magritek NMR software is used in a conventional manner to simultaneously interrogate the sample solution and the solvent. The free induction decay (FID) data is collected and converted into a spectrum. The spectrum consists of two complete proton NMR spectra that are disposed superposed on each other, sharing the identical chemical shift axis. The complete proton NMR spectrum for one capillary sample tube reveals the solute and solvent peaks, and the proton NMR spectrum for the second capillary tube reveals only the solvent peak. The two spectra are superimposed but derived from completely separate NMR signals, with completely overlapping solvent peaks. The two solvent peaks from the two capillary NMR tubes can be made to cancel each other so that the entire dynamic range of the NMR spectrometer receiver and analogue-to-digital converter can be utilized to detect and more accurately meter the intensities of the solute peaks. To accomplish the mutual annihilation of the NMR signals that produce the two solvent peaks, a radiofrequency electromagnetic pulse of finite duration and amplitude is provided to the central conductor via the matching capacitors from the AC power amplifier. The duration and amplitude of the RF pulse is adjusted to that the proton magnetization in the capillary NMR tube closest to the wire conductor executes a 360-degree rotation during the period of the RF pulse; the proton magnetization in the capillary NMR tubes furthest from the wire conductor will simultaneously execute a 180-degree rotation during the period of the RF pulse. Thus, the proton magnetization in both capillary NMR tubes will be directed opposite to each other, and a 90-degree RF pules generated by the Magritek NMR spectrometer is then used in a conventional manner to simultaneously immediately interrogate the sample solution and the solvent. The cancellation of the two solvent peaks results in a spectrum that only consists of solute peaks and a residual solvent peak. All data collection and processing is performed by the software package provided by Magritek.

While the invention has been described in connection with specific embodiments thereof, it will be understood that the inventive device is capable of further modifications. This patent application is intended to cover any variations, uses, or adaptations of the invention following, in general, the principles of the invention and including such departures from the present disclosure as come within known or customary practice within the art to which the invention pertains and as may be applied to the essential features herein before set forth.

What claimed is:

1. A method of simultaneously interrogating multiple samples using NMR spectroscopy, the method comprising:
inducing a first magnetic field;
inducing a flow of electricity through a conductive material, wherein the flow of electricity induces a second magnetic field;
placing a first sample in an additive magnetic field region, wherein a direction of the first magnetic field and a direction of the second magnetic field are aligned within the additive magnetic field region;
placing a second sample in a canceling magnetic field region, wherein the direction of the first magnetic field and the direction of the second magnetic field are opposed within the canceling magnetic field region; and
inducing a free induction decay (FID) of at least the first and second samples.

2. The method of claim 1, further comprising generating a graph of an NMR spectrum for at least the first and the second samples.

3. The method of claim 2, wherein the graph of the NMR spectrum has a signal intensity axis and a chemical shift axis, and wherein the NMR spectrum comprises at least a first spectrum and a second spectrum, the first spectrum being spaced out and distinct from the second spectrum along the chemical shift axis.

4. The method of claim 1, comprising:
placing a third sample in an intermediary magnetic field region, wherein the intermediary magnetic field region comprises an intermediary magnetic field having a magnitude less than a magnitude of the additive magnetic field and greater than a magnitude of the canceling magnetic field.

5. The method of claim 1, wherein the flow of electricity comprises one or more of a direct current or at least one excitation pulse of radio frequency (RF) alternating current.

6. The method of claim 5, wherein the at least one excitation pulse selectively acts on at least one of the first sample and the second sample.

7. A method for simultaneously interrogating multiple samples using NMR spectroscopy, the method comprising:
exposing a first sample to a first magnetic field in a sample space of an NMR spectrometer, wherein the sample space includes a conductor extending therethrough;
exposing a second sample to a second magnetic field in the sample space of the NMR spectrometer, wherein the first and second samples are positioned on opposing sides of the conductor;
monitoring a free induction decay (FID) of at least the first and the second samples; and
generating a NMR spectrum for at least the first and the second samples, wherein the NMR spectrum comprises a first spectrum corresponding to the first sample and a second spectrum corresponding to the second sample.

8. The method of claim 7, wherein the first magnetic field comprises an additive magnetic field comprising a combination of a transverse magnetic field and a circular magnetic field centered at the conductor, wherein the transverse magnetic field and the circular magnetic field are parallel proximate to the first sample.

9. The method of claim 7, wherein the first magnetic field comprises a canceling magnetic field comprising a combination of a transverse magnetic field and a circular magnetic field centered at the conductor, wherein the transverse magnetic field and the circular magnetic field are antiparallel proximate to the first sample.

10. The method of claim 7, wherein the first magnetic field comprises a combination of a transverse magnetic field and a circular magnetic field centered at the conductor, wherein the transverse magnetic field and the circular magnetic field are perpendicular proximate to the first sample.

11. The method of claim 7, wherein a distance between the first sample and the conductor is less than a distance between the second sample and the conductor.

12. The method of claim 7, further comprising inducing a sequence of radio frequency (RF) pulses in the conductor, such that the sequence selectively acts on the first sample.

13. The method of claim 12, wherein the sequence of RF pulses selectively prevents detection of the first sample in the NMR spectrum.

14. The method of claim 12, wherein the sequence of RF pulses selectively acts on the first sample such that a spectrum of the first sample cancels a portion of a spectrum of the second sample.

15. A device for simultaneous monitoring of multiple samples using a single sample NMR spectrometer, the device comprising:
an electrical conductor;
a compartmentalized sample holder having a center and a perimeter configured to accept a plurality of NMR sample tubes around the perimeter and further configured to allow the electrical conductor to pass through the center; and
a power source coupled to the electrical conductor, wherein the power source comprises a direct current (DC) power supply.

16. The device of claim 15, wherein the compartmentalized sample holder is configured to accept at least a first sample tube and a second sample tube, and wherein the first sample tube and the second sample tube are located on opposite sides of the conductor.

17. The device of claim 16, wherein the compartmentalized sample holder is configured to accept at least a third sample tube and a fourth sample tube, and wherein the third sample tube and the fourth sample tube are located on opposite sides of the conductor.

18. The device of claim 15, wherein the power source further comprises an alternating current (AC) power supply.

19. The device of claim 18, further comprising:
a first variable tuning capacitor; and
a second variable tuning capacitor, wherein the electrical conductor comprises a first terminal and a second terminal, the first variable tuning capacitor connected proximate to the first terminal and the second variable capacitor connected proximate to the second terminal and together form a resonant circuit.

20. The device of claim 18, wherein the AC power source comprises a radio frequency (RF) power amplifier.
